(19) United States
(12) Patent Application Publication
(10) Pub. No.: US 2023/0154828 A1
(43) Pub. Date: May 18, 2023

(54) FLUID COOLING FOR DIE STACKS

(71) Applicant: ADEIA SEMICONDUCTOR BONDING TECHNOLOGIES INC., San Jose, CA (US)

(72) Inventors: Belgacem Haba, Saratoga, CA (US); Christopher Aubuchon, Palo Alto, CA (US)

(21) Appl. No.: 18/056,070

(22) Filed: Nov. 16, 2022

Related U.S. Application Data
(60) Provisional application No. 63/264,261, filed on Nov. 18, 2021.

(51) Int. Cl. H01L 23/46; H01L 21/18

(52) U.S. Cl. CPC H01L 23/46; H01L 21/187

(57) ABSTRACT

The disclosed technology relates to microelectronic devices that can dissipate heat efficiently. In some aspects, such a microelectronic device includes a first semiconductor element and at least one second semiconductor element disposed on the first semiconductor element. The microelectronic device may further include a fluidic cooling unit disposed on the first semiconductor element. In some embodiment, the fluidic cooling unit may include a cavity structure to contain a fluid. In some embodiment, the fluidic cooling unit may include a thermal pathway to transfer heat away from the first semiconductor element.

### CROSS-REFERENCE TO RELATED APPLICATIONS

This application claims priority to U.S. Provisional Application No. 63/264,261, filed Nov. 18, 2021, titled “FLUID COOLING FOR DIE STACKS”, the content of which is incorporated by reference in its entirety.

### BACKGROUND

### Field

The field relates to dissipating heat in microelectronics, and particularly in microelectronics formed of directly bonded elements.

### Description of the Related Art

With the miniaturization and the high density integration of electronic components, the heat flux density in microelectronics is increasing. If the heat generated during the operation of microelectronics is not dissipated, the microelectronics may shut down or burn out. In particular, thermal dissipation is a serious problem in high-power devices.

### BRIEF DESCRIPTION OF THE DRAWINGS

Specific implementations will now be described with reference to the following drawings, which are provided by way of example, and not limitation.

FIG. 1 schematically illustrates a cross-sectional view of an example microelectronic system according to some embodiments of the disclosed technology.

FIG. 2 schematically illustrates a cross-sectional view of another example microelectronic system according to some embodiments of the disclosed technology.

FIG. 3A schematically illustrates a cross-sectional view of yet another example microelectronic system according to some embodiments of the disclosed technology.

FIG. 3B, FIG. 3C and FIG. 3D schematically illustrate cross-sectional views of example fluidic cooling units which may be used in the example microelectronic system of FIG. 3A.

FIG. 4 schematically illustrates a cross-sectional view of yet another example microelectronic system according to some embodiments of the disclosed technology.

### DETAILED DESCRIPTION

Microelectronic elements (e.g., dies/chips) can be stacked and bonded to one another to form a device. It is difficult to dissipate heat in a device with chip stacking, especially as chips get thinner. The use of chip joining methods such as adhesive bonding can make heat dissipation in the device less effective, as the adhesives may reduce or insulate heat transfer. Moreover, it is difficult to specifically lower the temperature in a desired portion of the device. For example, when packaging stacks of dies, heat dissipation is typically aided by heat sinks at the top of the stack, but extracting heat from lower dies is challenging. Especially in high power chips, thermal dissipation can be a serious problem. Accordingly, there remains a continuing need for improved techniques to dissipate heat in microelectronic devices.

Methods and structures are provided for redirecting thermal paths from lower dies in a stack to upper heat dissipation structures (e.g., heat sinks/heat pipes). In an aspect, a microelectronic device may include a fluidic cooling unit which can help remove heat from the device and redirect the heat flow in the device, for example reducing the heat flow through a certain chip in the device. For example, the fluidic cooling unit may be comprising a thermal pathway to transfer heat away from a lower/bottom semiconductor element. Such a fluidic cooling unit may occupy only a small footprint in a device.

In some embodiments, a lower wall of the fluidic cooling unit is directly bonded to another element (e.g., a lower die) in the device, thus avoiding the use of adhesives which may reduce heat transfer. The coefficient of thermal expansion (CTE) of the lower wall of the fluidic cooling unit may be chosen to substantially match with the CTE of that element, to avoid fractures or cracks in the bonded structure when the temperature rises during operation of the device. For example, the element to which the fluidic cooling unit is directly bonded to (e.g., the lower die) may be formed of silicon and the lower wall material may have a CTE similar to that of silicon.

In some embodiments, the fluidic cooling unit may include channels containing a fluid coolant which may be transported/circulated using a pump. In some embodiments, the fluidic cooling unit may include heat pipes containing a working fluid which can transfer heat via phase transition cycles. Compared to a neighboring chip, the fluidic cooling unit may be more efficient in transferring heat from a lower die, and thus the fluidic cooling unit can redirect the heat flow in the device and reduce the heat flow through that neighboring chip.

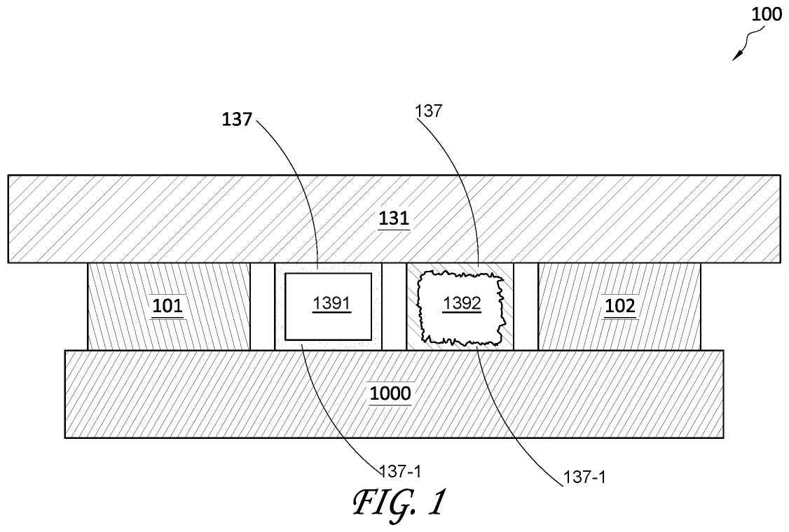

FIG. 1 schematically illustrates a cross-sectional view of an example microelectronic system 100 having stacked semiconductor elements (e.g., dies/chips) and a fluidic cooling unit 137 which connects to a heat sink 131 (e.g., a metal heat sink or a heat pipe with fluid coolant) at the top of the stack. For example, the fluidic cooling unit 137 may comprise a thermal pathway to transfer heat away from a lower/bottom semiconductor element 1000. The fluidic cooling unit 137 may be formed of semiconductor (e.g., silicon), metal, plastic, or any combination thereof, and may include a cavity structure (e.g., liquid channel 1391 or heatpipe 1392) and contain a fluid configured to transfer heat via circulation or phase transition cycles. For example, the fluid can include a gas or a liquid (e.g., water or dielectric liquid). The heat generated by the semiconductor elements 1000, 101 and/or 102 during operation may be transferred to the heat sink 131 and dissipated away from the system 100. For example, the fluid can be pumped into the cavity, e.g., the liquid channel 1391 or heatpipe 1392, by way of inlet conduits and can exit the cavity, e.g., the liquid channel 1391 or heatpipe 1392, by way of outlet conduits. The fluid can be conveyed from the outlet conduit to an external heat exchanger (not shown) where the fluid can be cooled, before returning to the cavity, e.g., the liquid channel 1391 or heatpipe 1392, by way of the inlet conduit. The fluidic cooling unit 137 and a one or a plurality of chips (e.g., “first die” 101 and “second die” 102) may be mounted on a base element 1000, which can be a die, wafer, etc. In some embodiments, “first die” or “second die” may be disposed inside of the fluidic cooling unit 137. In other embodiments, “first die” 101 or “second die” 102 may be disposed outside of the fluidic cooling unit 137.) The fluidic cooling unit 137 may be adjacent to at least one chip (e.g., at least “first die” 101) and thus reducing heat flow through the at least one chip.

In some embodiments, a bottom wall 137-1 of the fluidic cooling unit 137 has a CTE very close to that of the base element 1000. For example, base element 1000 may include a semiconductor material, such as silicon (Si), and the bottom wall 137-1 of the fluidic cooling unit 137 may have a CTE close to or matching that of the semiconductor material (e.g., Si). In one example, the bottom wall 137-1 of the fluidic cooling unit 137 may have a CTE lower than that of copper or under 10 μm/m° C. In some embodiments, the bottom wall 137-1 of the fluidic cooling unit 137 may be formed of an electrically non-conducting material, for example, a non-metal. In some embodiments, the bottom wall 137-1 of the fluidic cooling unit 137 may be formed of a semiconductor material, such as silicon (e.g., Si).

In some embodiments, the bottom wall 137-1 of the fluidic cooling unit 137 may be mounted to the base element 1000 by way of direct bonding without an intervening adhesive, such as nonconductive direct bonding techniques and/or hybrid direct bonding techniques. For example, the bottom wall 137-1 can be bonded to the chip 1000 using the ZIBOND® and/or DBI® processes configured for room temperature, atmospheric pressure direct bonding or the DBI® Ultra process configured for low-temperature hybrid bonding, which are commercially available from Adeia of San Jose, Calif. In some embodiments, the bottom wall 137-1 of the fluidic cooling unit 137 may be mounted to the bottom chip 1000 by way of solder bonding or adhesive bonding. In some embodiments, the bottom wall 137-1 of the fluidic cooling unit may be mounted to the bottom chip via a thermal interface material (TIM).

In some embodiments, the stacked semiconductor elements can be directly bonded to each other without an intervening adhesive. For example, “first die” 101 and/or “second die” 102 may be directly bonded to the base element 1000. In some embodiments, the top heat sink may be directly bonded to the semiconductor elements (e.g., “first die” 101 and/or “second die” 102) and/or the fluidic cooling unit 137, or may be mounted to the semiconductor elements and/or the fluidic cooling unit 137 via a thermal interface material (TIM). For example the direct bonding process may include the ZIBOND® and DBI® processes configured for room temperature, atmospheric pressure direct bonding or the DBI® Ultra process configured for low-temperature hybrid bonding, which are commercially available from Adeia of San Jose, Calif. The direct bonds can be between dielectric materials of the bonded elements and can also include conductive materials at or near the bond interface for direct hybrid bonding. The conductive materials at the bonding interface may be bonding pads formed in or over a redistribution layer (RDL) over a die, and/or passive electronic components.

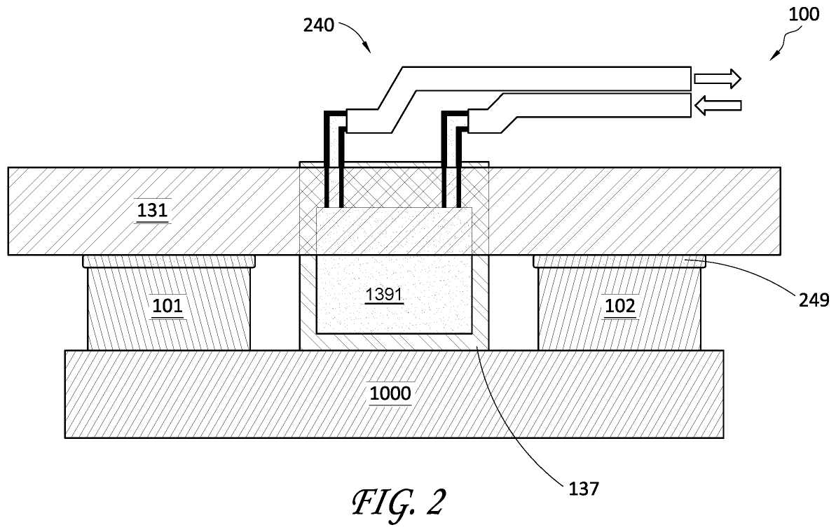

FIG. 2 illustrates a cross-sectional view of an example microelectronic system similar to that of FIG. 1, and like reference numbers are used to reference like features. However, the fluidic cooling unit is not connected to a heat sink. Instead, the fluidic cooling unit is directly connected to a fluidic system 240 (which may include pumps and additional fluidic channels) configured to transport/circulate the fluid coolant in the fluidic cooling unit and thus transfer the heat away from the microelectronic system. The top heat sink 131 may be mounted to the semiconductor elements via a thermal interface material (TIM) 249.

For example, a microelectronic device may include a first semiconductor element; a fluidic cooling unit directly bonded to the first semiconductor element without an adhesive, the fluidic cooling unit comprising a cavity structure to contain a fluid. In one embodiment, the microelectronic device further includes at least one second semiconductor element disposed on the first semiconductor element. In one embodiment, the fluidic cooling unit reduces a heat flow through the at least one second semiconductor element (e.g., the heat flow bypasses the at least one second semiconductor element). In one embodiment, the at least one second semiconductor element is directly bonded (e.g., direct hybrid bonded) to the first semiconductor element without an intervening adhesive. In one embodiment, the interface between the at least one second semiconductor element and the first semiconductor element comprises conductor-to-conductor and dielectric-to-dielectric direct bonds. In one embodiment, the microelectronic device further includes a heat sink disposed on the at least one second semiconductor element. In one embodiment, the fluidic cooling unit is configured to transfer heat from the first semiconductor element to the heat sink. In one embodiment, the heat sink is directly bonded to the at least one second semiconductor element without an intervening adhesive. In one embodiment, the first semiconductor element comprises an integrated device die. In one embodiment, the least one second semiconductor element comprises an integrated device die. In one embodiment, the fluid comprises a gas. In one embodiment, the fluid comprises a liquid. In one embodiment, the fluidic cooling unit reduces a heat flow through the at least one second semiconductor element (e.g., the heat flow bypasses the at least one second semiconductor element). In one embodiment, the least one second semiconductor element is disposed in the fluidic cooling unit. In one embodiment, the least one second semiconductor element is disposed outside of the fluidic cooling unit.

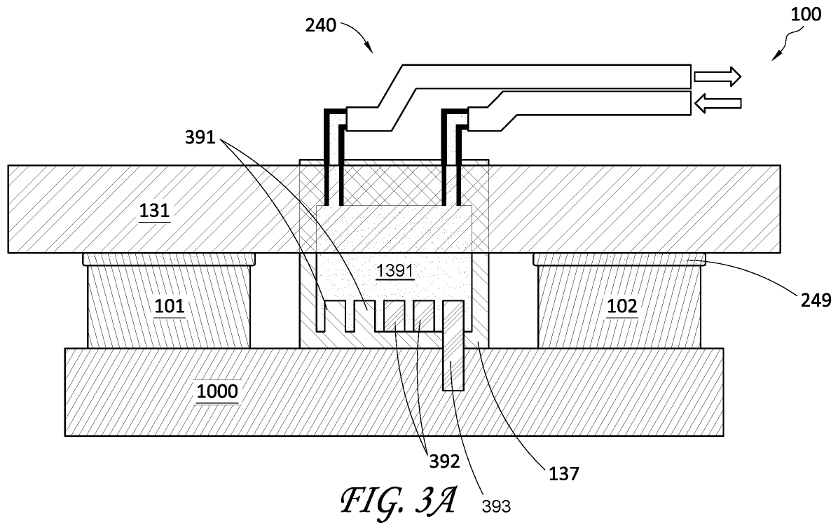

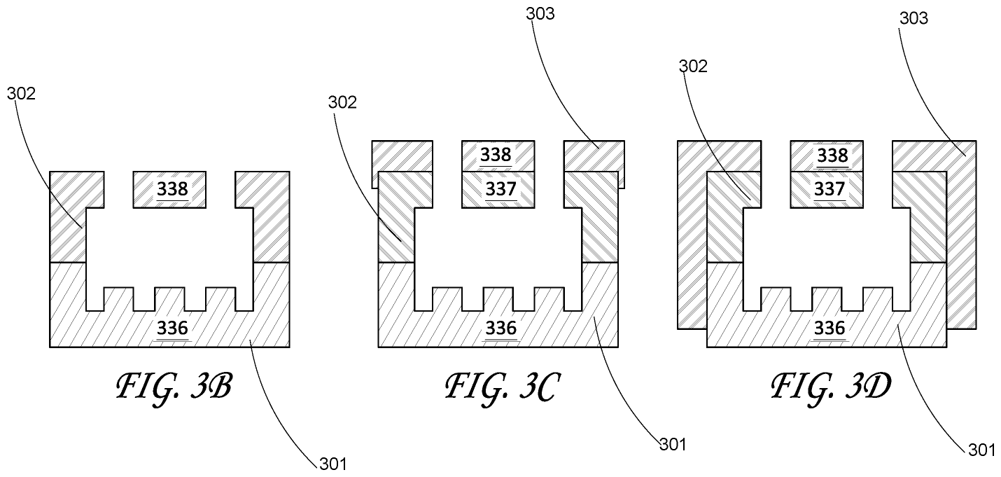

FIG. 3A illustrates a cross-sectional view of an example microelectronic system similar to that of FIG. 2, and like reference numbers are used to reference like features. However, the inner walls of the fluidic cooling unit may include finger features 391, 392 and 393 (e.g., fingers/pillars) which may help prevent laminar flow in the fluid. In some embodiments, the features 391, 392 and/or 393 may project inwardly into the cavity 1391. In some examples, the features may help promote turbulence in the fluid and thus facilitate fluid mixing and heat transport. Thus, a non-limiting advantage of the disclosed technology is that the features 391, 392 and/or 393 can help increase heat dissipation. In some embodiments, the inner walls of the fluidic cooling unit may be formed of a semiconductor material, such as silicon (Si). In some embodiments, the inner bottom wall of the fluidic cooling unit includes 391 formed of a semiconductor material (e.g., Si) or fingers 392 or 393 formed of a metal (e.g., copper). In one embodiment, some metal fingers may extend to the base element 1000. For example, a metal finger extending from the fluidic cooling unit to the bottom chip may be formed by directly bonding (e.g., direct hybrid bonding, for example, using DBI® processes) a metal feature of the fluidic cooling unit to a conductive via 393 of the bottom chip. The conductive via 393 can help conduct heat upwardly from the base element 1000 to the cavity 1391. The top heat sink 131 may be mounted to the semiconductor elements 101 and/or 102 via a thermal interface material (TIM).

In further embodiments shown in FIGS. 3B, 3C and 3D, the bottom/base portion 301 of the fluidic cooling unit and the top portion 302 of the fluidic cooling unit may be formed of different materials. In addition, the fluidic cooling unit may also include a capsule portion 303. For example, the bottom/base portion 301 of the fluidic cooling unit is formed of a semiconductor material, such as silicon (Si) 336. However, other portions of the the fluidic cooling unit, such as the top portion 302 or the capsule portion 303, may be formed of other semiconductor materials 337 or polymer/plastic materials 338.

For example, a microelectronic device may include a first semiconductor element; at least one second semiconductor element disposed on the first semiconductor element; and a fluidic cooling unit disposed on the first semiconductor element, the fluidic cooling unit comprising a cavity structure to contain a fluid, the fluidic cooling unit comprising a thermal pathway to transfer heat away from the first semiconductor element. Fluid is transported through the cavity structure by an active mechanism. In one embodiment, the cavity structure is formed of one or more electrically non-conducting or semiconducting materials. In one embodiment, the one or more electrically non-conducting or semiconducting materials comprise silicon or plastic. In one embodiment, an interior surface of the cavity structure comprises features configured to increase turbulence in the fluid. In one embodiment, the features comprise an array of pillars. In one embodiment, the features comprise silicon or metal. In one embodiment, the cavity structure comprises a bottom wall, and wherein the features are disposed on the bottom wall. In one embodiment, the features comprise a metal feature extending to the first semiconductor element. In one embodiment, the metal feature extending to the first semiconductor element is formed by directly bonding a feature disposed on the bottom wall to a conductive via disposed in the first semiconductor element. In one embodiment, the features are disposed on the first semiconductor element.

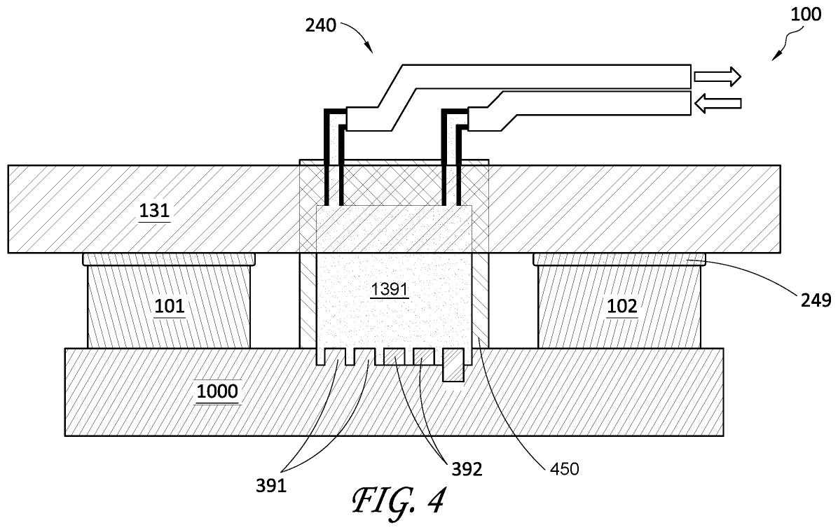

FIG. 4 illustrates a cross-sectional view of an example microelectronic system similar to that of FIG. 3A, and like reference numbers are used to reference like features. However, instead of mounting a pre-formed cavity, e.g., liquid channel 1391, structure to the base element 1000, the fluidic cooling unit is formed by attaching/bonding a cap structure 450 (without a bottom wall) to the bottom chip, thus forming a cavity, e.g., liquid channel 1391, which can contain the fluid. In some embodiments, the cap structure may be directly bonded (e.g., ZIBOND® or DBI®) to the bottom chip. In some embodiments, the portion of the bottom chip interfacing with the cavity, e.g., liquid channel 1391, may include features (e.g., semiconductor material (e.g., Si) or metal fingers) which may help prevent laminar flow/promote turbulence in the fluid. The top heat sink may be mounted to the semiconductor elements via a TIM.

For example, a microelectronic device may include a first semiconductor element; at least one second semiconductor element disposed on the first semiconductor element; and a fluidic cooling unit disposed on the first semiconductor element, the fluidic cooling unit comprising a cavity structure to contain a fluid, the fluidic cooling unit comprising a thermal pathway to transfer heat away from the first semiconductor element. Fluid is transported through the cavity structure by an active mechanism. In one embodiment, the cavity structure is formed by directly bonding a cap structure without a bottom wall to the first semiconductor element. In one embodiment, the cavity structure comprises a bottom wall disposed on the first semiconductor element, and wherein a coefficient of thermal expansion (CTE) of the bottom wall is substantially similar to a CTE of the first semiconductor element. In one embodiment, the first semiconductor element comprises silicon, wherein the cavity structure comprises a bottom wall disposed on the first semiconductor element, and wherein a coefficient of thermal expansion (CTE) of the bottom wall is substantially similar to the CTE of silicon. In one embodiment, the cavity structure comprises a bottom wall disposed on the first semiconductor element, and a coefficient of thermal expansion (CTE) of the bottom wall is lower than that of copper. In one embodiment, the cavity structure comprises a bottom wall disposed on the first semiconductor element, and wherein a coefficient of thermal expansion (CTE) of the bottom wall is lower than 10 μm/m° C. In one embodiment, the cavity structure comprises a bottom wall disposed on the first semiconductor element, and wherein the bottom wall comprises silicon. In one embodiment, the cavity structure comprises a bottom wall disposed on the first semiconductor element, and wherein the bottom wall is directly bonded to the first semiconductor element without an intervening adhesive. In one embodiment, the interface between the bottom wall and the first semiconductor element comprises dielectric-to-dielectric direct bonds

A method of forming the microelectronic device 100 may include providing a first semiconductor element; and bonding a second semiconductor element and a fluidic cooling unit to the first semiconductor element, such that the second semiconductor element and the fluidic cooling unit are disposed on the first semiconductor element, wherein the fluidic cooling unit comprises a cavity structure to contain a fluid, the fluidic cooling unit comprising a thermal pathway to transfer heat away from the first semiconductor element. In one embodiment, bonding the second semiconductor element comprises directly bonding the second semiconductor element to the first semiconductor element without an intervening adhesive. In one embodiment, the cavity structure comprises a bottom wall, and wherein bonding the fluidic cooling unit comprises directly bonding the bottom wall to the first semiconductor element without an intervening adhesive. In one embodiment, the method further includes forming the cavity structure by directly bonding a cap structure without a bottom wall to the first semiconductor element. In one embodiment, the second semiconductor element is disposed in the fluidic cooling unit. In one embodiment, the second semiconductor element is disposed outside of the fluidic cooling unit.

### Electronic Elements

A die can refer to any suitable type of integrated device die. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes.

### Examples of Direct Bonding Methods and Directly Bonded Structures

Various embodiments disclosed herein relate to directly bonded structures in which two elements can be directly bonded to one another without an intervening adhesive. Two or more electronic elements, which can be semiconductor elements (such as integrated device dies, wafers, etc.), may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric materials for direct bonding include but are not limited to inorganic dielectrics, such as silicon oxide, silicon nitride, or silicon oxynitride, or can include carbon, such as silicon carbide, silicon oxycarbonitride, silicon carbonitride or diamond-like carbon. In some embodiments, the dielectric materials do not comprise polymer materials, such as epoxy, resin or molding materials.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid direct bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments in the bonding tool described herein and, subsequently, the bonded structure can be annealed. Annealing can be performed in a separate apparatus. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 5 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. In embodiments described herein, whether a die or a substrate, the first element can be considered a host substrate and is mounted on a support in the bonding tool to receive the second element from a pick-and-place or robotic end effector. The second element of the illustrated embodiments comprises a die. In other arrangements, the second element can comprise a carrier or a flat panel. or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness. For example, the bonding layers may have a surface roughness of less than 2 nm root mean square (RMS) per micron, or less than 1 nm RMS per micron.

In various embodiments, metal-to-metal bonds between the contact pads in direct hybrid bonded structures can be joined such that conductive features grains, for example copper grains on the conductive features grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one aspect, the disclosed technology relates to a microelectronic device comprising: a first semiconductor element; at least one second semiconductor element disposed on the first semiconductor element; and a fluidic cooling unit disposed on the first semiconductor element, the fluidic cooling unit comprising a cavity structure to contain a fluid, the fluidic cooling unit comprising a thermal pathway to transfer heat away from the first semiconductor element.

In one embodiment, fluid is transported through the cavity structure by an active mechanism.

In one embodiment, the cavity structure is formed of one or more electrically non-conducting or semiconducting materials.

In one embodiment, the one or more electrically non-conducting or semiconducting materials comprise silicon or plastic.

In one embodiment, an interior surface of the cavity structure comprises features configured to increase turbulence in the fluid.

In one embodiment, the features comprise an array of pillars.

In one embodiment, the features comprise silicon or metal.

In one embodiment, the cavity structure comprises a bottom wall, and wherein the features are disposed on the bottom wall.

In one embodiment, the features comprise a metal feature extending to the first semiconductor element.

In one embodiment, the metal feature extending to the first semiconductor element is formed by directly bonding a feature disposed on the bottom wall to a conductive via disposed in the first semiconductor element.

In one embodiment, the features are disposed on the first semiconductor element.

In one embodiment, the cavity structure is formed by directly bonding a cap structure without a bottom wall to the first semiconductor element.

In one embodiment, the cavity structure comprises a bottom wall disposed on the first semiconductor element, and wherein a coefficient of thermal expansion (CTE) of the bottom wall is substantially similar to a CTE of the first semiconductor element.

In one embodiment, the first semiconductor element comprises silicon, wherein the cavity structure comprises a bottom wall disposed on the first semiconductor element, and wherein a coefficient of thermal expansion (CTE) of the bottom wall is substantially similar to the CTE of silicon.

In one embodiment, the cavity structure comprises a bottom wall disposed on the first semiconductor element, and wherein a coefficient of thermal expansion (CTE) of the bottom wall is lower than that of copper.

In one embodiment, the cavity structure comprises a bottom wall disposed on the first semiconductor element, and wherein a coefficient of thermal expansion (CTE) of the bottom wall is lower than 10 μm/m° C.

In one embodiment, the cavity structure comprises a bottom wall disposed on the first semiconductor element, and wherein the bottom wall comprises silicon.

In one embodiment, the cavity structure comprises a bottom wall disposed on the first semiconductor element, and wherein the bottom wall is directly bonded to the first semiconductor element without an intervening adhesive.

In one embodiment, the interface between the bottom wall and the first semiconductor element comprises dielectric-to-dielectric direct bonds.

In one embodiment, the cavity structure comprises a bottom wall disposed on the first semiconductor element, and wherein the bottom wall is bonded to the first semiconductor element by way of solder bonding.

In one embodiment, the cavity structure comprises a bottom wall disposed on the first semiconductor element, and wherein the bottom wall is bonded to the first semiconductor element by way of adhesive bonding.

In one embodiment, the cavity structure comprises a bottom wall disposed on the first semiconductor element, and wherein the bottom wall is bonded to the first semiconductor element by a thermal interface material (TIM).

In one embodiment, the at least one second semiconductor element is directly bonded (e.g., direct hybrid bonded) to the first semiconductor element without an intervening adhesive.

In one embodiment, the interface between the at least one second semiconductor element and the first semiconductor element comprises conductor-to-conductor and dielectric-to-dielectric direct bonds.

In one embodiment, the microelectronic device further includes a heat sink disposed on the at least one second semiconductor element

In one embodiment, the fluidic cooling unit is configured to transfer heat from the first semiconductor element to the heat sink.

In one embodiment, the heat sink is directly bonded to the at least one second semiconductor element without an intervening adhesive.

In one embodiment, the first semiconductor element comprises an integrated device die.

In one embodiment, the least one second semiconductor element comprises an integrated device die.

In one embodiment, the fluid comprises a gas.

In one embodiment, the fluid comprises a liquid.

In one embodiment, the fluidic cooling unit reduces a heat flow through the at least one second semiconductor element (e.g., the heat flow bypasses the at least one second semiconductor element).

In one embodiment, the least one second semiconductor element is disposed in the fluidic cooling unit.

In one embodiment, the least one second semiconductor element is disposed outside of the fluidic cooling unit.

In another aspect, the disclosed technology relates to a method of forming a microelectronic device, the method comprising: providing a first semiconductor element; and bonding a second semiconductor element and a fluidic cooling unit to the first semiconductor element, such that the second semiconductor element and the fluidic cooling unit are disposed on the first semiconductor element, wherein the fluidic cooling unit comprises a cavity structure to contain a fluid, the fluidic cooling unit comprising a thermal pathway to transfer heat away from the first semiconductor element.

In one embodiment, bonding the second semiconductor element comprises directly bonding the second semiconductor element to the first semiconductor element without an intervening adhesive.

In one embodiment, the cavity structure comprises a bottom wall, and wherein bonding the fluidic cooling unit comprises directly bonding the bottom wall to the first semiconductor element without an intervening adhesive.

In one embodiment, the method further includes forming the cavity structure by directly bonding a cap structure without a bottom wall to the first semiconductor element.

In one embodiment, the second semiconductor element is disposed in the fluidic cooling unit.

In one embodiment, the second semiconductor element is disposed outside of the fluidic cooling unit.

In another aspect, the disclosed technology relates to a microelectronic device comprising: a first semiconductor element; a fluidic cooling unit directly bonded to the first semiconductor element without an adhesive, the fluidic cooling unit comprising a cavity structure to contain a fluid.

In one embodiment, the microelectronic device further includes at least one second semiconductor element disposed on the first semiconductor element.

In one embodiment, the fluidic cooling unit reduces a heat flow through the at least one second semiconductor element (e.g., the heat flow bypasses the at least one second semiconductor element).

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A microelectronic device comprising:
a first semiconductor element;
at least one second semiconductor element disposed on the first semiconductor element; and
a fluidic cooling unit disposed on the first semiconductor element, the fluidic cooling unit comprising a cavity structure to contain a fluid, the fluidic cooling unit comprising a thermal pathway to transfer heat away from the first semiconductor element.

2. The microelectronic device of claim 1, wherein fluid is transported through the cavity structure by an active mechanism.

3. The microelectronic device of claim 1, wherein the cavity structure is formed of one or more electrically non-conducting or semiconducting materials.

4. The microelectronic device of claim 1, wherein an interior surface of the cavity structure comprises features configured to increase turbulence in the fluid.

5. The microelectronic device of claim 1, wherein the cavity structure is formed by directly bonding a cap structure without a bottom wall to the first semiconductor element.

6. The microelectronic device of claim 1, wherein the cavity structure comprises a bottom wall disposed on the first semiconductor element, and wherein a coefficient of thermal expansion (CTE) of the bottom wall is substantially similar to a CTE of the first semiconductor element.

7. The microelectronic device of claim 1, wherein the first semiconductor element comprises silicon, wherein the cavity structure comprises a bottom wall disposed on the first semiconductor element, and wherein a coefficient of thermal expansion (CTE) of the bottom wall is substantially similar to the CTE of silicon.

8. The microelectronic device of claim 1, wherein the cavity structure comprises a bottom wall disposed on the first semiconductor element, and wherein a coefficient of thermal expansion (CTE) of the bottom wall is lower than that of copper.

9. The microelectronic device of claim 1, wherein the cavity structure comprises a bottom wall disposed on the first semiconductor element, and wherein a coefficient of thermal expansion (CTE) of the bottom wall is lower than 10 μm/m° C.

10. The microelectronic device of claim 1, wherein the cavity structure comprises a bottom wall disposed on the first semiconductor element, and wherein the bottom wall comprises silicon.

11. The microelectronic device of claim 1, wherein the cavity structure comprises a bottom wall disposed on the first semiconductor element, and wherein the bottom wall is directly bonded to the first semiconductor element without an intervening adhesive.

12. The microelectronic device of claim 1, wherein the cavity structure comprises a bottom wall disposed on the first semiconductor element, and wherein the bottom wall is bonded to the first semiconductor element by way of solder bonding.

13. The microelectronic device of claim 1, wherein the cavity structure comprises a bottom wall disposed on the first semiconductor element, and wherein the bottom wall is bonded to the first semiconductor element by way of adhesive bonding.

14. The microelectronic device of claim 1, wherein the cavity structure comprises a bottom wall disposed on the first semiconductor element, and wherein the bottom wall is bonded to the first semiconductor element by a thermal interface material (TIM).

15. The microelectronic device of claim 1, wherein the at least one second semiconductor element is direct hybrid bonded to the first semiconductor element without an intervening adhesive.

16. The microelectronic device of claim 1, further comprising a heat sink disposed on the at least one second semiconductor element

17. A method of forming a microelectronic device, the method comprising:
providing a first semiconductor element; and
bonding a second semiconductor element and a fluidic cooling unit to the first semiconductor element, such that the second semiconductor element and the fluidic cooling unit are disposed on the first semiconductor element,
wherein the fluidic cooling unit comprises a cavity structure to contain a fluid, the fluidic cooling unit comprising a thermal pathway to transfer heat away from the first semiconductor element.

18. The method of claim 17, wherein bonding the second semiconductor element comprises directly bonding the second semiconductor element to the first semiconductor element without an intervening adhesive.

19. The method of claim 17, wherein the cavity structure comprises a bottom wall, and wherein bonding the fluidic cooling unit comprises directly bonding the bottom wall to the first semiconductor element without an intervening adhesive.

20. The method of claim 17, further comprising forming the cavity structure by directly bonding a cap structure without a bottom wall to the first semiconductor element.

21. A microelectronic device comprising:
a first semiconductor element;
a fluidic cooling unit directly bonded to the first semiconductor element without an adhesive, the fluidic cooling unit comprising a cavity structure to contain a fluid.

22. The microelectronic device of claim 21, further comprising at least one second semiconductor element disposed on the first semiconductor element.

23. The microelectronic device of claim 22, wherein the fluidic cooling unit reduces a heat flow through the at least one second semiconductor element.
